(19) United States
(12) Patent Application Publication
(10) Pub. No.: US 2010/0268500 A1
(43) Pub. Date: Oct. 21, 2010

(54) METHOD AND DEVICE FOR THE IDENTIFICATION OF A DELAY-SUSCEPTIBLE CONTROL PATH, CONTROL DEVICE AND COMPUTER PROGRAM PRODUCT

(76) Inventors: Lutz Augenstein, Kieselbronn (DE); Bernd Lamb, Waldbronn (DE); Bernd-Markus Pfeiffer, Woerth (DE); Klaus Wendelberger, St. Leon-Rot (DE)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 12/445,801

(22) PCT Filed: Oct. 18, 2007
(86) PCT No.: PCT/EP2007/061170

§ 371 Date: Jun. 17, 2010

(30) Foreign Application Priority Data
Oct. 18, 2006 (DE) 10 2006 049 124.6

(51) Int. Cl. G06F 19/00; G05B 19/00; G01R 29/00

(52) U.S. Cl. 702/79

(57) ABSTRACT

A method for identifying a delay-susceptible control path in the control of a steam generator and a device constructed for carrying out the method are provided. A model structure of the steam generator is specified, consisting of an unknown time-variable Nth-order delay element and a known integrator. Also used for the identification are measurements of the fuel mass flow, the turbine stream mass flow, and the live stream pressure which arises in the steam accumulator behind the steam generator after the removal of the turbine steam mass flow. Using these online measurements and the model structure, the live steam mass flow at the output of the steam generator is derived by calculation. In this way, the input value and the output value of the Nth-order delay element are determined and, using an estimation method, the parameters of a continuous transmission function of the Nth-order delay element are also determined online.

### CROSS REFERENCE TO RELATED APPLICATIONS

This application is the US National Stage of International Application No. PCT/EP2007/061170, filed Oct. 18, 2007 and claims the benefit thereof. The International Application claims the benefits of German application No. 10 2006 049 124.6 DE filed Oct. 18, 2006, both of the applications are incorporated by reference herein in their entirety.

### FIELD OF INVENTION

The invention relates to a method for the identification of a delay-susceptible control path in the control of a steam generator as well as to a device embodied for executing the method. The invention further relates to a control device as well as to a computer program product.

### BACKGROUND OF INVENTION

The quality of control of model-based controlling depends on how well the dynamic behavior of a real process is mapped by the model. In the case of a steam generator with turbine in a coal-fired power station the dynamic behavior of the overall system varies over time because of the non-linear behavior of different units such as coal crushers, fresh air blowers, suction paths etc. as well as especially the fluctuations in the raw material quality of the coal. In addition the process dynamics changes over time as a result of contamination and wear.

For controlling such time-variant processes the dynamic behavior of the process has previously only been considered to the extent that, starting from a time-invariant model, in a comprehensive series of trials, dependencies of the process dynamics of the main influencing variables have been determined. This information was stored in corresponding maps which in their turn were incorporated into the control process. The slow variance of the dynamic over time through contamination or wear often had to be countered in expensive on-site servicing by the controlling having to be reset again and again at regular intervals. In such cases the control quality is always limited by the inaccuracy of the model.

### SUMMARY OF INVENTION

Another approach to enabling time-variant processes to be better controlled consists of adapting the model to the current circumstances in the process. In an adaptive control the time-variable system behavior caused by the fluctuations in path parameters is first detected in a suitable manner and with the aid of the information thus obtained an adjustment of the controller parameters is undertaken. In the so-called “self-tuning” adaption method the fluctuating parameters are determined from the measurement of input and output variables of the path. Such a determination of system parameters from system variables which change over time is referred to as identification.

An object of the invention is to specify a method for identification of a delay-susceptible control path, so that an improved quality of control is achieved in the control of a steam generator. A further object of the present invention is to specify a corresponding apparatus which enables the inventive method to be executed. A further object of the invention consists of specifying a control device which uses the result of the identification of the control path. A computer program product is also to be specified.

This object is achieved by the features of the independent claims. Advantageous embodiments are reflected respectively in the dependent claims.

The invention advantageously enables an online identification for the dynamic process model of a steam generator. In such cases a model structure of the steam generator consisting of a time-variant Nth-order delay element N and an integrator is specified. The mass fuel flow which is fed to the steam generator, the turbine steam mass flow which is taken from the output of the steam generator pipe and the fresh steam pressure which obtains in the steam vessel beyond the steam generator after removal of the turbine steam mass flow are used as measured values. By means of these measured values obtained online the fresh steam mass flow at the output of the steam generator is computed, since this is not accessible and thus also not measurable. In this way the input variable of the Nth-order delay element and the output variables of the same are determined, so that by means of an estimation process the parameters of a continuous transmission function of the Nth-order delay element will likewise be determined online. The estimated parameters are subsequently converted into the time constants of a delay element with N independent time constants. In a next step, by comparison of the N time constants, areas in the time curves of the individual time constants are defined, in which the time constants are almost the same. Within these areas the time constants of an Nth-order delay element with the same time constants for the delay element of the predetermined model structure are determined from the N independent time constants. If the time constant of the delay element is determined, the entire dynamic model of the steam generator is also identified.

The inventive approach enables time-variant parameters of a continuous transmission function to be identified from sampled measurement data. This makes a permanent adaptation of the process model to the behavior of the real plant possible. The adapted model is a basis for an adaptive control which offers a power station operator a higher quality of control especially for changes in the raw material quality and for load changes, and which contributes to reducing energy consumption, environmental stress and wear on the plant. An especial advantage of the invention lies in the fact that the permanent monitoring and online execution of the parameter estimation with insufficient stimulus avoids the output of irrelevant estimation results to the overlaid control.

In an embodiment of the invention the fuel mass flow is advantageously multiplied by an amplification factor which is composed from the calorific value of the fuel and the efficiency of the steam generator. This means an improved mapping of the dynamic model of the steam generator onto the real process, and thus an additional improvement in control quality.

In a further embodiment of the invention the measured values are multiplied by weighting factors, with the weighting factors for measured values lying further back in the past being smaller than the weighting factors of current measured values. To this end for example a forgetting factor is introduced into the computations. Faults resulting from measurement data further back in time are in this way advantageously avoided and thus a higher accuracy of the inventive method is obtained.

### BRIEF DESCRIPTION OF THE DRAWINGS

The invention will be explained below with reference to an exemplary embodiment shown in the drawings. The figures show:

FIG. 1 a block diagram of a control path for steam generator and turbine

FIG. 2 a comparison of the online curves of measurement data of the fuel mass flow, of the computed fresh steam mass flow and an example for the estimated parameters for a third-order delay element.

FIG. 3 a schematic diagram of the control device On the basis of FIG. 1 the control technology structure model RS of the steam generator is illustrated. The variables which change over time as well as functional relationships are illustrated by suitable graphical symbols and assembled into a structure diagram.

### DETAILED DESCRIPTION OF INVENTION

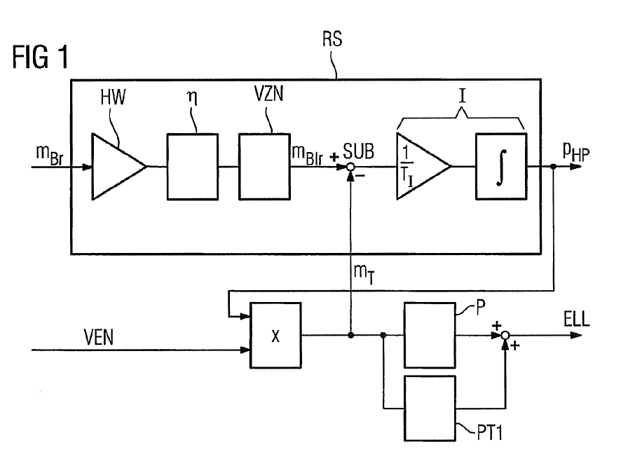

As input variable the fuel mass flow mBr is fed to the steam generator which is represented in the drawing by the control path RS, For steam generation for example coal crushed into coal dust in coal crushing units is burnt, which heats up water conducted above the burner in pipes into steam. The different calorific value of the coal is taken into account in the structure model RS by an amplification element HW. In addition each combustion and thereby the steam generation has a different efficiency, which is shown in FIG. 1 as a separate block η. These factors, which predominantly relate to the quality of the coal, are to be regarded from the control technology standpoint as factors with which the input variable of the fuel mass flow mBr will be multiplied.

The dynamic behavior of coal crushing, combustion and steam generation will be modeled in this exemplary embodiment approximately by a time-variant Nth-order delay element VZN. As already explained, the dynamic behavior of the steam generator varies over time because of the fluctuating raw material quality.

At the output of the delay element VZN a fresh steam mass flow mBlr is discharged. The fresh steam is subsequently fed to a steam reservoir or vessel. Taken from this and fed to the turbine is a turbine steam mass flow mT. To this end a subtraction element SUB is shown in FIG. 1. The integrated difference between the two mass flows mBlr and mT is proportional to the steam pressure pHP in the steam reservoir, and as opposed to the fresh steam mass flow mBlr, this is a measurable variable. In the structure model RS specified here an integrator I is shown for carrying out the integration. This is required to be time invariant. The integration time constant TI of the steam vessel is required to be known.

The current-generating subsystem is not part of the control path RS and is only shown here as a extra. It comprises generator and turbine. A manipulated variable is the valve setting VEN of the turbine input valve via which the flow of steam to the turbine is controlled. Turbine and generator are modeled by the parallel circuit of a P and PT1 element, since a part of the fresh steam moves directly from the high pressure area of the turbine to the generator and a further part of the steam is fed behind the high-pressure area of the turbine back into the steam vessel. The PT1 element thus represents the circuit in conjunction with the intermediate circuit superheater.

The steam-generating and the current-generating subsystem are coupled via the turbine steam mass flow mT and the steam pressure pHP. Increasing the turbine steam mass flow by opening the valve VEN initially leads to a reduction in the steam pressure. This in its turn reduces the turbine steam mass flow and thereby increases the steam pressure pHP again. It is also basically true that the turbine flow mass flow mT is proportional to the generated electrical power ELL and can be determined computationally from this.

On the basis of the path module RS for the steam generator described with reference to FIG. 1, the methodology of the online identification of the steam generator will now be explained.

Basically the identification of the control path of the steam generator means the determination of the transmission behavior of the unknown delay element VZN, which represents the dynamic behavior of the steam generator. If the transmission function and the time constant of the delay element is determined, the process is identified. An estimation method is used for identification of the parameter of the transmission function of the delay element. A permanent monitoring of the parameter estimation should occur at the same time in order to prevent the output of incorrect estimation results to the overlaid controlling.

The basis of the inventive online identification, as well as the predetermined model structure, are thus measured values of the fuel mass flow mBr of the turbine steam mass flow mT and of the fresh steam pressure pHP sampled in constant time steps. An identification in real time is achieved in this way.

To determine the transmission function of the delay element the input and output variables of the delay element VZN must be determined in a next step. The input variable is the fuel mass flow mBr. The output variable is the fresh steam mass flow mBlr. The fresh steam mass flow mBlr is however generally difficult to determine using measurement technology. This is thus reconstructed computationally. The fresh steam mass flow mBlr is computed for known integration time constant TI of the pressure vessel from the measurable variables of the fresh steam pressure pHP and of the turbine steam mass flow mT in the following manner (with TA representing the sampling time and k a runtime parameter for the sampling):

$${\dot{m}}_{Blr} ( k + 1 ) = {\dot{m}}_{T} ( k + 1 ) + {T}_{1} \frac{{P}_{HP} ( k + 1 ) - {P}_{HP} ( k )}{{T}_{A}}$$

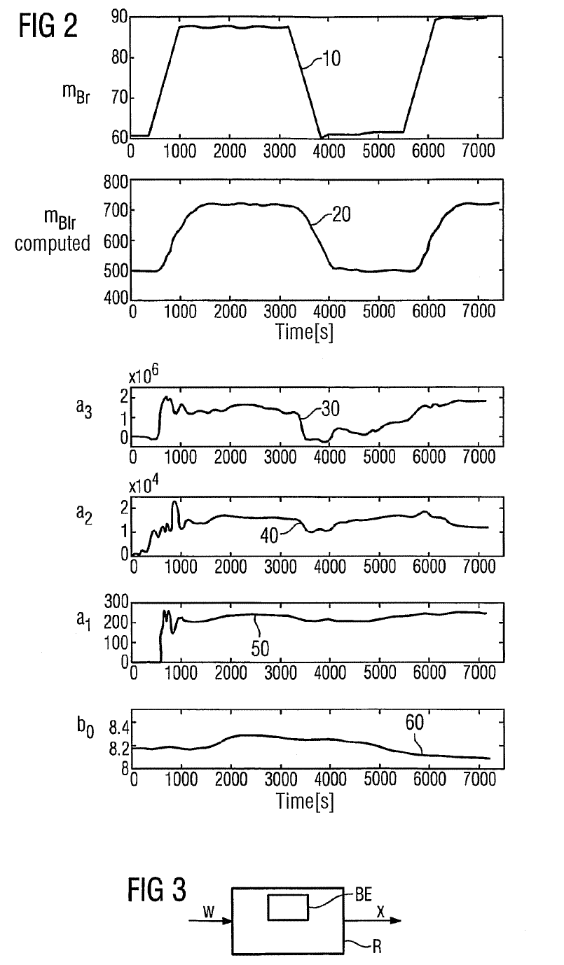

FIG. 2 shows typical timing curves for the measurable input variable of the fuel mass flow mBr in curve 10 and the computed output variables mBlr in curve 20. The measured values are recorded in this case in the 5 s grid. The fictitious fresh steam mass flow mBlr that represents the output variable of the steam generator is computed with an integration time constant of the steam vessel of 85 s.

The Nth-order delay element VZN is assumed below as a typical PT3 element.

The aim is to determine the continuous transmission function of the PT3 element in this step

$$\begin{matrix}G = \frac{y ( s )}{u ( s )} \\ = \frac{K}{( 1 + {T}_{1} s ) ( 1 + {T}_{2} s ) ( 1 + {T}_{3} s )} \\ = \frac{{b}_{0}}{1 + {a}_{1} s + {a}_{2} {s}^{2} + {a}_{3} {s}^{3}} .\end{matrix}$$

The meanings of the terms are as follows

G(s) the Laplace-transformed transmission function of the PT3 element (also referred to as s transmission function)

y(s) the process output signal

u(s) the process input signal

T1, T2, T3 are the individual independent time constants

a1, a2, a3 and b0 the process parameters which are determined by means of an estimation method.

In this exemplary embodiment a recursive Least-Squares parameter estimation with a discrete root filter method in the form of information is used. Simultaneously an exponentially decreasing weighting of measurement data further back in time is undertaken using forgetting factors. The non-measurable derivations of the input and output variables needed for this are determined with the aid of a state variable filter.

Shown as examples in FIG. 2 are the parameters of the transmission function estimated online from real measurement data of curves 10 and 20. The curves 30, 40, 50 and 60 in this case represent the development over time of the corresponding parameters a3, a2, a1 and b0. The recursive discrete root filter method in information form with a forgetting factor of 0.995 is used. A time constant of 80 s is used in this case for the state variable filter, in order to effectively suppress high-frequency noise in the fuel and fresh steam mass flow data.

Basically other known estimation methods can also be used to estimate the parameters such as the Prediction Error Method or other root filter methods.

It should also be noted below that in this exemplary embodiment the dynamic behavior of the steam generator and vessel is described as a series connection of three first-order delay elements with the same time constants, although with a real path there would never be three precisely identical time constants. The demand for three identical time constants however cannot be directly fulfilled since all recursive parameter estimation methods only estimate the parameters (polynomial coefficients) of a transmission function, but no time constants. However the time constants of the PT3 element can still be determined subsequent to the parameter estimation from the estimated independent time constants.

After successful estimation of the discrete parameters a1, a2, a3 and b0 these are still to be converted to the corresponding continuous-time amplification and time constants.

From the above equation for the transmission function in the conversion into time constants a non-linear equation system in the following form is produced:

T₁+T₂+T₁=a₁

T₁T₂+T₂T₃+T₁T₃=a₂

T₁T₂T₃=a₃

With the simplified assumption of three identical time constants T1=12=13=1 the numerical value of this triple time constant can be computed from each of the parameters. With small differences between the three independent time constants T1, T2 and T3 the assumption made is appropriate. This gives three ways of computing the same time constant, namely the time constant of the PT3 element of the steam generator sought:

$$T ( {a}_{1} ) = \frac{{a}_{1}}{3} , T ( {a}_{2} ) = \sqrt{\frac{{a}_{1}}{3}} , T ( {a}_{3} ) = \sqrt[3]{{a}_{3}}$$

Based on these values the relevance of the estimation results can now be determined.

It should also be noted that this is an online identification and the recursive estimator should be active at any time in order to identify the system parameters. With insufficient excitation or too much disturbance however the estimator does not deliver any meaningful estimation parameters and thus no meaningful time constants either. Thus a monitoring level is necessary which tests the estimation results delivered for plausibility and decides on their validity. Different test criteria are set up for this purpose. Only if all criteria are fulfilled at the same time is the currently computed average sum time constant accepted and output.

Sensible interval limits are specified as criteria for example, i.e. a lower limit Tmin and an upper limits Tmax of an interval is specified within which the average time constant of the steam generator sought may be located.

In addition the gradient behavior can be checked and a so-called prediction error criterion applied. Thus at the monitoring level use is made of the fact that three independent time constants for a time constant of the delay element PT3 sought are present.

In pure graphical terms this step is represented such that the curve shapes of the three time constants T1, T2, T3 are compared and a check is made by means of the above criteria and that In this way areas of the curve shapes can be determined in which the time constants T1, T2, T3 are approximately the same. Within these areas the time constant T of a 3rd-order delay element 3 with same time constants for the delay element of the predetermined model structure can be determined from the three independent time constants T1, T2, T3, whereby the overall process is identified here in the case of the steam generator.

The result of the identification is passed on in the form of a continuous-time model to the overlaid control. The adapted model is thus part of an adaptive control of the steam generator and the turbine, as illustrated in FIG. 3.

FIG. 3 shows the structure diagram of a control device R. The control device is supplied with the guide variable w. The control variable x is output at the output of the control device. Part of the control device is one or more arithmetic units BE, in which the identification of the control path for the controlling of the steam generator is computed online in accordance with the inventive method.

1.-9. (canceled)

10. A method for identification of a delay-susceptible control path in a control of a steam generator, the method comprising:
predetermining a control technology model structure for the steam generator which has a time-variant Nth-order delay element,
by the control technology model structure:
directing a fuel mass flow as an input variable to the time-variant Nth-order delay element,
issuing a fresh steam mass flow as an output variable from the time-variant Nth-order delay element,
arranging a subtraction element beyond the time-variant Nth-order delay element in which a turbine steam mass flow is subtracted from the fresh steam mass flow forming a difference value, and
feeding the difference value between the fresh steam mass flow and the turbine steam mass flow to an integrator, an output of which represents a fresh steam pressure;
determining while online a measured value of the fuel mass flow, a measured value of the fresh steam pressure, and a measured value of the turbine steam mass flow;
recalculating the fresh steam mass flow using the control technology model structure including the measured value of the fresh steam pressure and the measured value of the turbine steam mass flow and taking into account a predetermined time constant of the integrator;
determining while online a plurality of parameters of a continuous transmission function of the time-variant Nth-order delay element using an estimation method which includes the measured value of the fuel mass flow and the fresh steam mass flow;
converting the plurality of parameters of the continuous transmission function of the time-variant Nth-order delay element into a plurality of time constants of the time-variant Nth-order delay element with a plurality of independent time constants; and
determining a plurality of time ranges during the control of the steam generator in which each value of the plurality of time constants is approximately equal and assigning the value for each of the plurality of time constants to each value of the plurality of time constants of the time-variant Nth-order delay element.

11. The method as claimed in claim 10, wherein the time variant Nth-order delay element is a third-order time-variant delay element.

12. The method as claimed in claim 10, wherein the fuel mass flow is multiplied by an amplification factor.

13. The method as claimed in claim 10, wherein the integrator is embodied time-invariant.

14. The method as claimed in claim 10, wherein a plurality of measured values which include the measured value of the fuel mass flow, the measured value of the fresh steam pressure, and the measured value of the turbine steam mass flow, are multiplied by a plurality of weighting factors, with the plurality of weighting factors for the plurality of older measured values being smaller than the plurality of weighting factors of the plurality of current measured values.

15. The method as claimed in claim 10, wherein a recursive least-squares parameter estimation of the continuous transmission function with a discrete root filter method in an infatuation form is used as the estimation method.

16. The method as claimed in claim 10, wherein a prediction error method is used as the estimation method.

17. A device for identification of a delay-susceptible control path for a control of a steam generator, comprising:
a computation unit for executing a method for identification of a delay-susceptible control path in a control of a steam generator, the method comprising:
predetermining a control technology model structure for the steam generator which has a time-variant Nth-order delay element,
by the control technology model structure:
directing a fuel mass flow as an input variable to the time-variant Nth-order delay element,
issuing a fresh steam mass flow as an output variable from the time-variant Nth-order delay element,
arranging a subtraction element beyond the time-variant Nth-order delay element in which a turbine steam mass flow is subtracted from the fresh steam mass flow forming a difference value, and
feeding the difference value between the fresh steam mass flow and the turbine steam mass flow to an integrator, an output of which represents a fresh steam pressure,
determining while online a measured value of the fuel mass flow, a measured value of the fresh steam pressure, and a measured value of the turbine steam mass flow,
recalculating the fresh steam mass flow using the control technology model structure including the measured value of the fresh steam pressure and the measured value of the turbine steam mass flow and taking into account a predetermined time constant of the integrator,
determining while online a plurality of parameters of a continuous transmission function of the time-variant Nth-order delay element using an estimation method which includes the measured value of the fuel mass flow and the fresh steam mass flow,
converting the plurality of parameters of the continuous transmission function of the time-variant Nth-order delay element into a plurality of time constants of the time-variant Nth-order delay element with a plurality of independent time constants, and
determining a plurality of time ranges during the control of the steam generator in which each value of the plurality of time constants is approximately equal and assigning the value for each of the plurality of time constants to each value of the plurality of time constants of the time-variant Nth-order delay element.

18. The device for identification of a delay-susceptible control path for the control of a steam generator as claimed in claim 17, wherein a control device for a steam generator which features a delay-susceptible control path is used.

19. A computer readable storage medium having a program of instructions executable by a computer for performing the steps of:
predetermining a control technology model structure for the steam generator which has a time-variant Nth-order delay element,
by the control technology model structure:
directing a fuel mass flow as an input variable to the time-variant Nth-order delay element,
issuing a fresh steam mass flow as an output variable from the time-variant Nth-order delay element,
arranging a subtraction element beyond the time-variant Nth-order delay element in which a turbine steam mass flow is subtracted from the fresh steam mass flow forming a difference value, and
feeding the difference value between the fresh steam mass flow and the turbine steam mass flow to an integrator, an output of which represents a fresh steam pressure;
determining while online a measured value of the fuel mass flow, a measured value of the fresh steam pressure, and a measured value of the turbine steam mass flow;
recalculating the fresh steam mass flow using the control technology model structure including the measured value of the fresh steam pressure and the measured value of the turbine steam mass flow and taking into account a predetermined time constant of the integrator;
determining while online a plurality of parameters of a continuous transmission function of the time-variant Nth-order delay element using an estimation method which includes the measured value of the fuel mass flow and the fresh steam mass flow;
converting the plurality of parameters of the continuous transmission function of the time-variant Nth-order delay element into a plurality of time constants of the time-variant Nth-order delay element with a plurality of independent time constants; and
determining a plurality of time ranges during the control of the steam generator in which each value of the plurality of time constants is approximately equal and assigning the value for each of the plurality of time constants to each value of the plurality of time constants of the time-variant Nth-order delay element.

20. The computer readable storage medium as claimed in claim 19, wherein the time variant Nth-order delay element is a third-order time-variant delay element.

21. The computer readable storage medium as claimed in claim 19, wherein the fuel mass flow is multiplied by an amplification factor.

22. The computer readable storage medium as claimed in claim 19, wherein the integrator is embodied time-invariant.

23. The computer readable storage medium as claimed in claim 19, wherein a plurality of measured values which include the measured value of the fuel mass flow, the measured value of the fresh steam pressure, and the measured value of the turbine steam mass flow, are multiplied by a plurality of weighting factors, with the plurality of weighting factors for the plurality of older measured values being smaller than the plurality of weighting factors of the plurality of current measured values.

24. The computer readable storage medium as claimed in claim 19, wherein a recursive least-squares parameter estimation of the continuous transmission function with a discrete root filter method in an information faint is used as the estimation method.

25. The computer readable storage medium as claimed in claim 19, wherein a prediction error method is used as the estimation method.
